(19) United States
(12) Patent Application Publication
(10) Pub. No.: US 2021/0372869 A1
(43) Pub. Date: Dec. 2, 2021

(54) METHOD OF ANALYZING STRAIN OF THIN FILM BY USING STC METHOD

(71) Applicant: Wonjae CHANG, Seoul (KR)

(72) Inventor: Wonjae CHANG, Seoul (KR)

(21) Appl. No.: 16/888,248

(22) Filed: May 29, 2020

(51) Int. Cl. G01L 1/25

(52) U.S. Cl. CPC G01L 1/25

(57) ABSTRACT

The present invention relates to a method of analyzing strain of a thin film by using a Strain Tensor Using Computational Fourier Transform Moiré (STC) method, and the method includes: receiving two Bragg peaks selected from a reciprocal lattice image obtained by Fourier transforming a two-dimensional (2D) lattice image of a thin film; shifting the two received Bragg peaks to an origin point of the reciprocal lattice image; calculating a moiré fringe pattern by Fourier-inverse-transforming the two Bragg peaks shifted to the origin point; calculating a strain tensor by differentiating the calculated moiré fringe pattern; and analyzing strain of the thin film by using the calculated strain tensor. The present invention, it is possible to obtain a considerably accurate strain analysis result with minimal errors even in the case where strain of a thin film is complex, and measure shear strain, as well as axial strain, of a thin film.

### TECHNICAL FIELD

The present invention relates to a method of analyzing strain of a thin film by using a Strain Tensor Using Computational Fourier Transform Moiré (STC) method, and more particularly, to a method of analyzing strain of a thin film by using a strain tensor calculated by two Bragg peaks selected from a reciprocal lattice image obtained by Fourier transforming a two-dimensional lattice image of a thin film.

### BACKGROUND ART

A method of analyzing strain of a thin film is recognized as an important part in a compound semiconductor device and the like, and is being significantly discussed in the strain study related to defect, and the importance of the method of measuring strain of a thin film is gradually increasing.

As a prior art of the method of measuring strain of a thin film, there is a Geometrical Phase Analysis (GPA) method, and the GPA method requires a phase image in a strain calculating process and in order to remove discontinuous values existing in the phase image, an unwrapping process needs to be used, so that when the strain is not regular and is complex, there are problems in that it is considerably difficult to create an unwrapping algorithm and the measurement of the strain may include considerable errors.

As one of the methods for overcoming the problems, there is suggested a Computational Fourier Transform Moiré (CFTM) method which is capable of measuring local strain of an atom plane by Fourier transforming an image, such as a High-Resolution Transmission Electron Microscopy (HRTEM) image or a Scanning Transmission Electron Microscopy (STEM) image, representing a crystal structure. The CFTM method does not require an unwrapping process, so that unlike the GPA method, the CFTM has an advantage in minimal errors even when a strain ratio of the thin film is not regular and the strain is complex. However, there is a problem in that the CFTM method calculates only axial strain in measuring strain of a thin film.

### SUMMARY OF THE INVENTION

An object of the present invention is to provide a method of analyzing strain of a thin film by using a Strain Tensor Using Computational Fourier Transform Moiré (STC) method, which does not require an unwrapping process, thereby obtaining a considerably accurate analysis result with minimal errors even when the strain of the thin film is complex.

Another object of the present invention is to provide a method of analyzing strain of a thin film by using an STC method, which is capable of measuring shear strain, as well as axial strain, of the thin film, by using 2×2 strain tensor.

An exemplary embodiment of the present invention provides a method of analyzing strain of a thin film by using a Strain Tensor Using Computational Fourier Transform Moiré (STC) method, the method including: receiving two Bragg peaks selected from a reciprocal lattice image obtained by Fourier transforming a two-dimensional (2D) lattice image of a thin film; shifting the two received Bragg peaks to an origin point of the reciprocal lattice image; calculating a moiré fringe pattern by Fourier-inverse-transforming the two Bragg peaks shifted to the origin point; calculating a strain tensor by differentiating the calculated moiré fringe pattern; and analyzing strain of the thin film by using the calculated strain tensor.

The 2D lattice image of the thin film may be a High-Resolution Transmission Electron Microscopy (HRTEM) image or a High-Angle Annular Dark-Field Scanning Transmission Electron Microscopy (HAADF-STEM) image.

The two received Bragg peaks may be non-colinear Bragg peaks.

The two received Bragg peaks may be the two Bragg peaks selected in order of largest intensity among the Bragg peaks except for the origin point in the reciprocal lattice image obtained by Fourier transforming the 2D lattice image of the thin film.

For each of the two received Bragg peaks, Bragg peak information at a desired position in the reciprocal lattice image obtained by Fourier transforming the 2D lattice image of the thin film may be selected by using a mask which makes an internal region of the mask maintain original information and an external region of the mask have 0.

The strain tensor is a 2×2 strain tensor.

According to the method of analyzing strain of the thin film by using the STC method according to the present invention, it is possible to obtain a considerably accurate strain analysis result with minimal errors even in the case where strain of the thin film is complex.

According to the method of analyzing strain of the thin film by using the STC method according to the present invention, it is possible to measure shear strain, as well as axial strain, of a thin film.

### BRIEF DESCRIPTION OF THE DRAWINGS

FIG. 1 is a flowchart illustrating a method of analyzing strain of a thin film by using a Strain Tensor Using Computational Fourier Transform Moiré (STC) method according to an exemplary embodiment of the present invention.

FIG. 2 is a diagram illustrating a computer generated two-dimensional (2D) lattice image of a thin film and a reciprocal lattice image obtained by Fourier transforming the two-dimensional lattice image of the thin film.

FIG. 3A is a 2D image as a result of an analysis of the strain of the thin film by using the STC method according to the exemplary embodiment of the present invention.

FIG. 3B is a graph illustrating a line-scan profile of FIG. 3A.

FIG. 4 is a diagram illustrating a reciprocal lattice image for simulation of g3 peak noise.

FIG. 5A to 5C are graphs illustrating the comparison of the analysis results of the thin films according to the STC method according to the exemplary embodiment of the present invention, the conventional CFTM method, and the conventional GPA method according to the related art.

FIG. 5D is a diagram illustrating a result of an analysis of strain of a thin film by using the STC method according to the exemplary embodiment of the present invention.

FIG. 5E is a diagram illustrating a result of an analysis of strain of a thin film by using the CFTM method according to the related art.

FIG. 5F is a diagram illustrating a result of an analysis of strain of a thin film by using the GPA method according to the related art.

### DETAILED DESCRIPTION

Hereinafter, the present invention will be described in detail with reference to the accompanying drawings. In this case, like reference numerals refer to like elements in each drawing. Further, the detailed description of an already published function and/or configuration will be omitted. In the contents disclosed below, the parts needed for understanding operations according to various exemplary embodiments are mainly described, and the description of the elements which may make the subject matter of the description unclear will be omitted. Further, some constituent elements in the drawing may be exaggerated, omitted, or schematically illustrated. A size of each constituent element does not reflect the actual size entirely, and therefore, the contents described herein are not limited by the relative size or spacing of the constituent elements drawn in the respective drawings.

Terms including an ordinal number, such as a first and a second, may be used for describing various constituent elements, but the constituent elements are not limited by the terms. The terms are used only for the purpose of discriminating one constituent element from another constituent element.

Singular expressions used herein include plural expressions unless they have definitely opposite meanings in the context.

In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

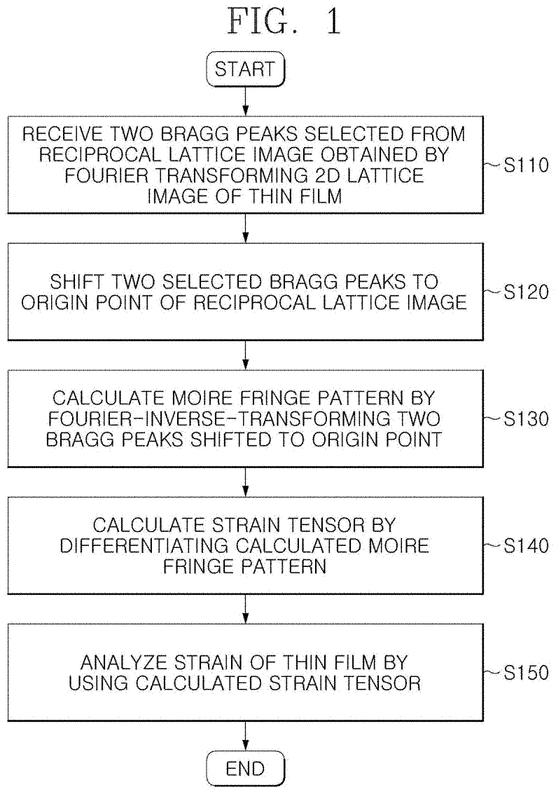

FIG. 1 is a flowchart illustrating a method of analyzing strain of a thin film by using a Strain Tensor Using Computational Fourier Transform Moiré (STC) method according to an exemplary embodiment of the present invention.

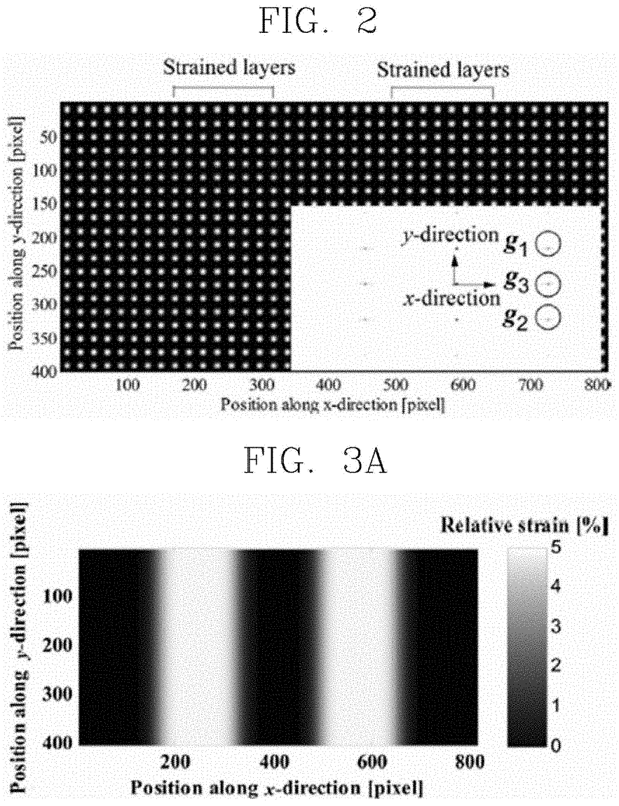

FIG. 2 is a diagram illustrating a two-dimensional (2D) lattice image of a thin film and a reciprocal lattice image obtained by Fourier transforming the two-dimensional lattice image of the thin film.

Hereinafter, a method of analyzing strain of a thin film by using an STC method according to an exemplary embodiment of the present invention will be described in detail with reference to FIGS. 1 and 2.

Two Bragg peaks selected from a reciprocal lattice image obtained by Fourier transforming a 2D lattice image of a thin film may be input (S110). A target of which a strain region is to be measured is a material having a lattice structure, and for example, a thin film. The 2D lattice image of the thin film may be a High-Resolution Transmission Electron Microscopy (HRTEM) image or a High-Angle Annular Dark-Field Scanning Transmission Electron Microscopy (HAADF-STEM) image. The 2D lattice image of the thin film according to the exemplary embodiment of the present invention may be the 2D lattice image of the thin film illustrated in FIG. 2. The 2D lattice image may include strained layers.

The HRTEM or HAADF-STEM image is an image of a discontinuous cycle, so that image intensity of position r may be represented as Equation 1.

$$I ( r ) = {Σ}_{n} {H}_{n} exp ( 2 {ig}_{n} \cdot r ) , \qquad ( Equation 1 )$$

Herein, Hₙ is a Fourier coefficient of the image.

The subscript n of gₙ represents each Bragg peak (reciprocal lattice vector, which represents a specific set (specific fringe) of the 2D image, has a direction vertical to the specific fringe, and has a magnitude of a reciprocal number of a specific fringe spacing), and n is a real number. The reciprocal lattice vector gₙ of a specific set of the 2D lattice image pattern may have the same length as a reciprocal number of a pattern gap of the 2D lattice image. The reciprocal lattice vector gₙ is vertical to the pattern of the 2D lattice image.

Equation 1 is the equation expressing the case where there is no strain in the 2D lattice image.

When the 2D lattice image includes strain by displacement u(r), the position including the strain is r−u(r), not r, and may be expressed by Equation 2.

r=r−u(r). (Equation 2)

When r−u(r) is put in r of Equation 1, the 2D lattice image including the strain may be expressed by Equation 3.

$$I ( r ) = {Σ}_{n} {H}_{n} ( r ) exp \{ 2 i {g}_{n} \cdot ( r - u ( r ) ) \} , \qquad ( Equation 3 )$$

Herein, an amplitude term Hₙ(r) may also be a position dependent value.

The reciprocal lattice image according to the exemplary embodiment of the present invention may be the reciprocal lattice image illustrated at a right-lower end in the 2D lattice image of the thin film illustrated in FIG. 2. The reciprocal lattice image is the Fourier transformed image, so that the reciprocal lattice image may be a point symmetric image based on an origin point.

When the 2D lattice image I(r) including the strain is Fourier transformed, the reciprocal lattice image I(k) may be obtained by using Equation 4.

I(k)=∫_{A}I(r)exp{−i2πk·r}dr. (Equation 4)

When Equation 3 is put in Equation 4, Equation 5 may be obtained.

$$I ( k ) = {\int }_{A } {Σ}_{n} {H}_{n} ( r ) exp \{ i 2 {g}_{n} \cdot ( r - u ( r ) ) \} exp ( - i 2 k \cdot r ) dr , \qquad ( Equation 5 )$$

Then, when Equation 5 is organized, the reciprocal lattice image I(k) may be expressed like Equation 6.

$$I ( k ) = {\int }_{A} {Σ}_{n} {H}_{n} ( r ) exp \{ - i 2 {g}_{n} \cdot u ( r ) \} exp \{ - i 2 ( k - {g}_{n} ) \cdot r \} dr . \qquad ( Equation 6 )$$

The two Bragg peaks may be the non-colinear Bragg peaks. The reciprocal lattice image is the point symmetric image based on the origin point, so that the selection of the two origin-symmetric Bragg peaks in the reciprocal lattice image is the same as the selection of the one same Bragg peak, so that as the two Bragg peaks, it may be preferable to select the non-colinear Bragg peak. Referring to FIG. 2, the case where two are selected from g1, g2, and g3 may be the case where the non-colinear pole linear Bragg peaks are selected.

The two received Bragg peaks may be the two Bragg peaks selected in order of largest intensity among the Bragg peaks except for the origin point in the obtained reciprocal lattice image.

Then, the two received Bragg peaks may be the Bragg peaks selected by using a mask, and more particularly, the method using the mask may be the method of selecting each Bragg peak information at a desired position by using a mask which makes an internal region of the mask maintain original information and an external region of the mask have 0. By the method, the two Bragg peaks at the desired positions may be selected by using the two masks. respectively.

As the exemplary embodiment of the present invention, when g1 and g2 are selected as the two Bragg peaks having the largest intensity, a reciprocal lattice image of the Bragg peak g1 may be expressed as Equation 7.

$${I}_{1} ( k ) = {\int }_{A} {Σ}_{n} {H}_{n} ( r ) exp \{ - i 2 {g}_{1} \cdot u ( r ) \} exp \{ - i 2 ( k - {g}_{1} ) \cdot r \} dr . \qquad ( Equation 7 )$$

The two received Bragg peaks may be shifted to the origin point of the reciprocal lattice image (S120). As an example of the present invention, when g1 and g2 are selected as the two Bragg peaks, each of g1 and g2 may be shifted to the original point.

As an example of the present invention, as expressed in Equation 8, the Bragg peak g1 may be shifted to the origin point, and a reciprocal lattice image of the origin-shifted Bragg peak g1 may be expressed as Equation 9.

$$\begin{matrix}\overline{k} = k - {g}_{1} , & ( Equation 8 ) \\ {I}_{1} ( \overline{k} ) = {\int }_{A} {Σ}_{n} {H}_{n} ( r ) exp \{ - i 2 {g}_{1} \cdot u ( r ) \} exp \{ - i 2 \overline{k} \cdot r \} dr . & ( Equation 9 )\end{matrix}$$

A moiré fringe pattern may be calculated by Fourier-inverse-transforming the two origin-shifted Bragg peaks (S130). The Fourier-inverse-transforming of the reciprocal lattice image of the shifted Bragg peak may reconfigure the moiré pattern to provide a very sensitive analysis of local strain in the 2D image.

Equation 9 of the reciprocal lattice image of the origin-shifted Bragg peak g1 may be organized to Equation 10.

I₁(k̅)=f[Hₙ(r)exp{−i2πg₁·u(r)}]. (Equation 10)

A moiré fringe pattern like Equation 11a may be calculated by Fourier-inverse-transforming the reciprocal lattice image of the origin-shifted Bragg peak.

A moiré fringe pattern like Equation 11b may be calculated by Fourier-inverse-transforming a reciprocal lattice image of the origin-shifted Bragg peak g2 by the same method.

F⁻¹[I₁(k̅)]=Hₙ(r)exp{−i2πg₁·u(r)}. (Equation 11a)

F⁻¹[I₂(k̅)]=Hₙ(r)exp{−i2πg₂·u(r)}. (Equation 11b)

A strain tensor may be calculated by differentiating the calculated moiré fringe pattern (S140). The strain tensor may be the 2×2 strain tensor.

When Equation 11a and Equation 11b that are the moiré fringe patterns are differentiated, Equation 12a and Equation 12b may be obtained as the results.

F⁻¹[i2πk̅I₁(k̅)]=−i2πV̅{g₁·u(r)}Hₙ(r)exp{−i2πg₁·u(r)} (Equation 12a)

F⁻¹[i2πk̅I₂(k̅)]=−i2πV̅{g₂·u(r)}Hₙ(r)exp{−i2πg₂·u(r)}. (Equation 12b)

Equation 12a and Equation 12b may be expressed as Equation 13a and Equation 13b.

$$\begin{matrix}∇ \{ {g}_{1} \cdot u ( r ) \} = \frac{- {F}^{- 1} [ \overline{k} {I}_{1} ( \overline{k} ) ]}{{F}^{- 1} [ {I}_{1} ( \overline{k} ) ]} & ( Equation 13 a ) \\ ∇ \{ {g}_{2} \cdot u ( r ) \} = \frac{- {F}^{- 1} [ \overline{k} {I}_{2} ( \overline{k} ) ]}{{F}^{- 1} [ {I}_{2} ( \overline{k} ) ]} . & ( Equation 13 b )\end{matrix}$$

Equation 13a and Equation 13b may be expanded as Equation 14a and Equation 14b.

$$\begin{matrix}∇ \{ {g}_{1 x} {u}_{x} ( r ) + {g}_{1 y} {u}_{y} ( r ) \} = \frac{- {F}^{- 1} [ \overline{k} {I}_{1} ( \overline{k} ) ]}{{F}^{- 1} [ {I}_{1} ( \overline{k} ) ]} & ( Equation 14 a ) \\ ∇ \{ {g}_{2 x} {u}_{x} ( r ) + {g}_{2 y} {u}_{y} ( r ) \} \vert = \frac{- {F}^{- 1} [ \overline{k} {I}_{2} ( \overline{k} ) ]}{{F}^{- 1} [ I {\vert}_{2} ( \overline{k} ) ]} , & ( Equation 14 b )\end{matrix}$$

Herein, the subscripts x and y are the x and y components in the reciprocal lattice vector g and a displacement field u(r) at the position r of the image.

When Equation 14a and Equation 14b are reorganized, a displacement gradient vector may be expressed as Equation 15.

$$∇ ( \begin{matrix}{u}_{x} ( r ) \\ {u}_{y} ( r )\end{matrix} ) = \frac{1}{{g}_{1 x} {g}_{2 y} - {g}_{1 y} {g}_{2 x}} [ \begin{matrix}{g}_{2 y} & - {g}_{1 y} \\ - {g}_{2 x} & {g}_{1 x}\end{matrix} ] ( \begin{matrix}\frac{- {F}^{- 1} [ \overline{k} {I}_{1} ( \overline{k} ) ]}{{F}^{- 1} [ {I}_{1} ( \overline{k} ) ]} \\ \frac{- {F}^{- 1} [ \overline{k} {I}_{2} ( \overline{k} ) ]}{{F}^{- 1} [ {I}_{2} ( \overline{k} ) ]}\end{matrix} ) . \qquad ( Equation 15 )$$

When a direction differentiation is applied to the displacement gradient vector, the 2×2 strain tensor may be expressed as Equation 16.

$$e = ( \begin{matrix}{e}_{xx} & {e}_{xy} \\ {e}_{yx} & {e}_{yy}\end{matrix} ) = ( \begin{matrix}\frac{\partial {u}_{x}}{\partial x} & \frac{\partial {u}_{x}}{\partial y} \\ \frac{\partial {u}_{y}}{\partial x} & \frac{\partial {u}_{y}}{\partial y}\end{matrix} ) = ( \begin{matrix}{n}_{1} \cdot ∇ {u}_{x} ( r ) & {n}_{2} \cdot ∇ {u}_{x} ( r ) \\ {n}_{1} \cdot ∇ {u}_{y} ( r ) & {n}_{2} \cdot ∇ {u}_{y} ( r )\end{matrix} ) , \qquad ( Equation 16 )$$

Herein, n₁ and n₂ are unit vectors according to an x-direction and a y-direction, respectively.

Then, each constituent element of the 2×2 strain tensor using the STC method may be calculated as described below.

An x-directional derived function eₓₓ in an x-directional displacement field may be defined as Equation 17a.

$${e}_{xx} = \frac{{g}_{1 y} \frac{{F}^{- 1} [ \overline{k} \cdot {n}_{1} {I}_{2} ( \overline{k} ) ]}{{F}^{- 1} [ {I}_{2} ( \overline{k} ) ]} - {g}_{2 y} \frac{{F}^{- 1} [ \overline{k} \cdot {n}_{1} {I}_{1} ( \overline{k} ) ]}{{F}^{- 1} [ {I}_{1} ( \overline{k} ) ]}}{{g}_{1 x} {g}_{2 y} - {g}_{1 y} {g}_{2 x}} \qquad ( Equation 17 a )$$

A y-directional derived function e_{xy} in the x-directional displacement field may be defined as Equation 17b.

$${e}_{xy} = \frac{{g}_{1 y} \frac{{F}^{- 1} [ \overline{k} \cdot {n}_{2} {I}_{2} ( \overline{k} ) ]}{{F}^{- 1} [ {I}_{2} ( \overline{k} ) ]} - {g}_{2 y} \frac{{F}^{- 1} [ \overline{k} \cdot {n}_{2} {I}_{1} ( \overline{k} ) ]}{{F}^{- 1} [ {I}_{1} ( \overline{k} ) ]}}{{g}_{1 x} {g}_{2 y} - {g}_{1 y} {g}_{2 x}} \qquad ( Equation 17 b )$$

An x-directional derived function e_{yx} in a y-directional displacement field may be defined as Equation 17c.

$${e}_{yx} = \frac{{g}_{2 x} \frac{{F}^{- 1} [ \overline{k} \cdot {n}_{1} {I}_{1} ( \overline{k} ) ]}{{F}^{- 1} [ {I}_{1} ( \overline{k} ) ]} - {g}_{1 x} \frac{{F}^{- 1} [ \overline{k} \cdot {n}_{1} {I}_{2} ( \overline{k} ) ]}{{F}^{- 1} [ {I}_{2} ( \overline{k} ) ]}}{{g}_{1 x} {g}_{2 y} - {g}_{1 y} {g}_{2 x}} \qquad ( Equation 17 c )$$

A y-directional derived function e_{yy} in the y-directional displacement field may be defined as Equation 17d.

$${e}_{yy} = \frac{{g}_{2 x} \frac{{F}^{- 1} [ \overline{k} \cdot {n}_{2} {I}_{1} ( \overline{k} ) ]}{{F}^{- 1} [ {I}_{1} ( \overline{k} ) ]} - {g}_{1 x} \frac{{F}^{- 1} [ \overline{k} \cdot {n}_{2} {I}_{2} ( \overline{k} ) ]}{{F}^{- 1} [ {I}_{2} ( \overline{k} ) ]}}{{g}_{1 x} {g}_{2 y} - {g}_{1 y} {g}_{2 x}} \qquad ( Equation 17 d )$$

The STC method is a direct method for analyzing strain. Accordingly, the 2×2 strain tensor may be directly calculated through the Fourier inverse transform of the differentiation of the reciprocal lattice image.

The strain of the thin film may be analyzed by using the calculated strain tensor (S150). When the calculated strain tensor is used, the shear-directional component, as well as the axial-directional component, of the thin film is included, so that there is an effect in measuring shear strain, as well as the axial strain of the thin film.

Accordingly, according to the method of analyzing strain of the thin film by using the STC method according to the present invention, an unwrapping process is not required, so that it is possible to obtain a considerably accurate analysis result with minimal errors even in the case where strain of the thin film is complex.

Further, according to the method of analyzing strain of the thin film by using the STC method according to the present invention, it is possible to measure shear strain, as well as axial strain, of a thin film by using the 2×2 strain tensor.

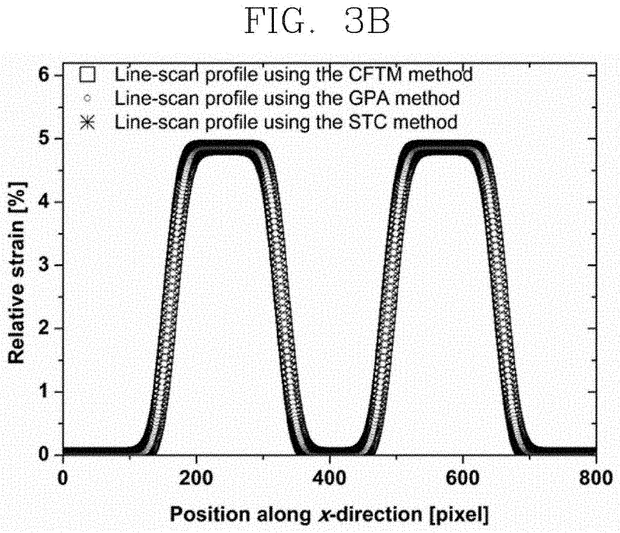

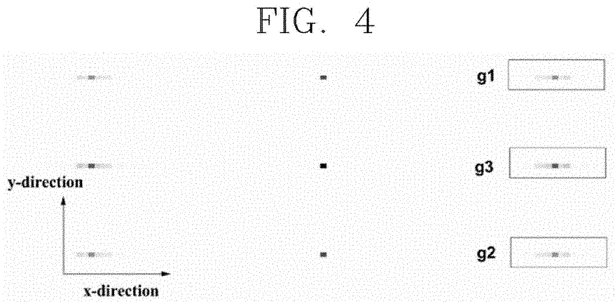

FIG. 3A is a 2D image as a result of an analysis of the strain of the thin film by using the STC method according to the exemplary embodiment of the present invention.

FIG. 3B is a graph illustrating a line-scan profile of FIG. 3A.

FIG. 2 illustrates the 2D lattice image of the thin film including the strained layers and the reciprocal lattice image obtained by Fourier transforming the 2D lattice image of the thin film.

When the two independent Bragg peaks g1 and g2 illustrated in FIG. 2 are selected and the strain of the thin film is analyzed by using the STC method according to the exemplary embodiment of the present invention, it is possible to obtain the result illustrated in FIG. 3A.

Then, when the CFTM method and the GPA method according to the related art is used, eₓₓ or e_{yy} may be calculated by selecting the Bragg peak in the x-axis direction or the y-axis direction illustrated in FIG. 2. For example, when the result according to the selection of a single Bragg peak g3 by using the conventional CFTM method and the GPA method is compared with the result according to the use of the STC method according to the exemplary embodiment of the present invention, it is possible to obtain the result illustrated in FIG. 3B. Referring to FIG. 3B, a line-scan profile represents a strain of 4.857% in the x-direction, and the two methods are accurately matched.

According to the GPA method that is the related art, an unwrapping process is required, but the STC method according to the exemplary embodiment of the present invention does not require an unwrapping process, thereby being more efficient.

Accordingly, in measuring the result in the axial direction that is one direction, the STC method according to the exemplary embodiment of the present invention may obtain the same train analysis result as that of the CFTM method and the GPA method.

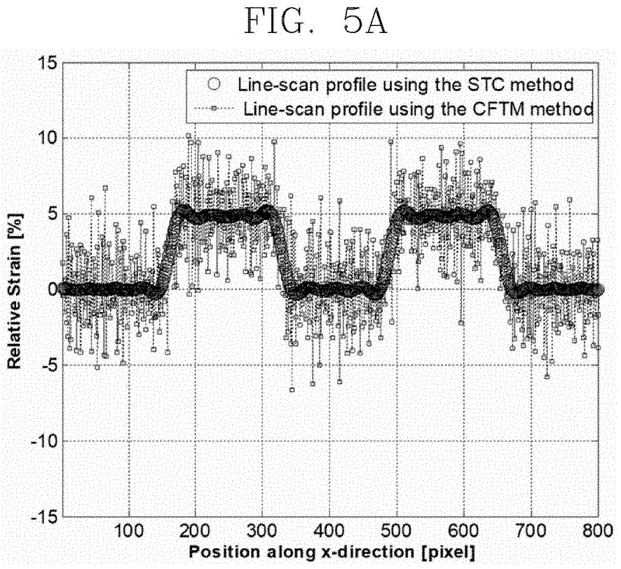

FIG. 4 is a diagram illustrating a reciprocal lattice image for simulation of g3 peak noise. Quadrangles illustrated in FIG. 4B illustrate examples of masks for selecting peaks g1, g2, and g3, respectively.

When the STC method according to the exemplary embodiment of the present invention is used, two independent Bragg peaks g1 and g2 illustrated in FIG. 4 may be selected, and for comparison with this, when the CFTM method that is the related art is used, one Bragg peak g3 illustrated in FIG. 4B may be selected.

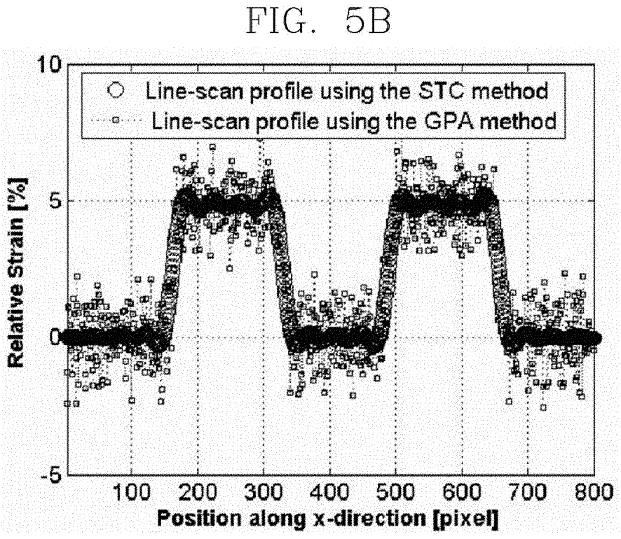

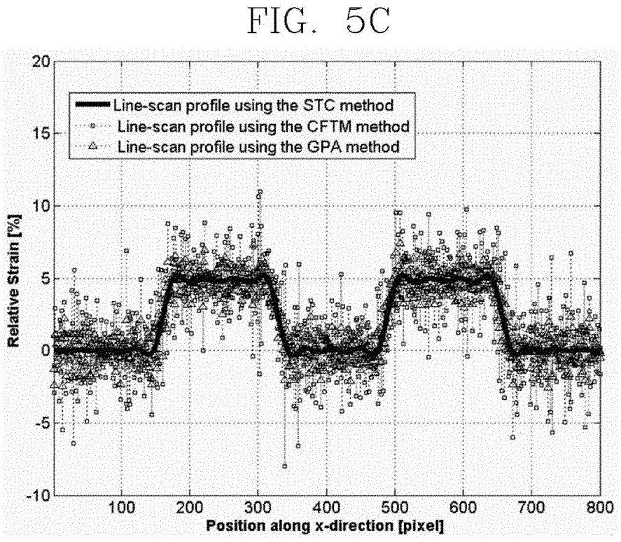

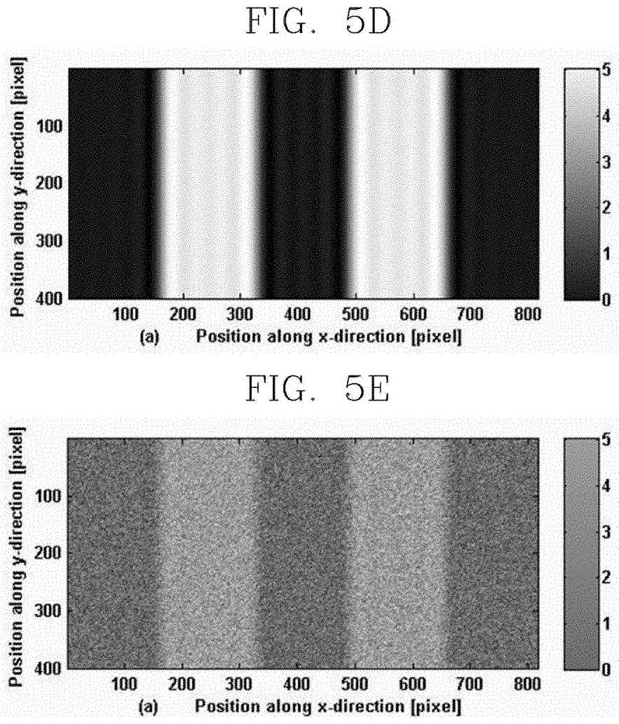

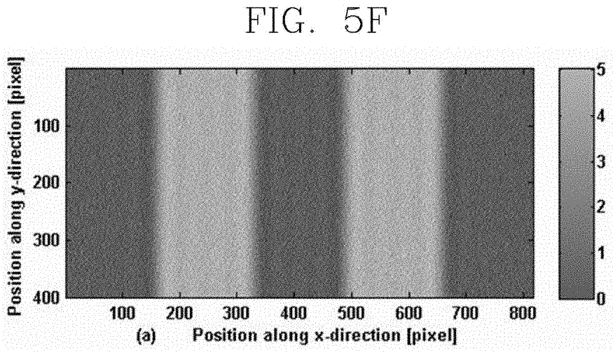

FIGS. 5A to 5C are graphs illustrating the comparison of the strain analysis results of the strain of the thin films according to the STC method according to the exemplary embodiment of the present invention, the CFIM method according to the related art, and the GPA (GEOMETRICAL PHASE ANALYSIS) according to the related art.

Referring to FIGS. 5A to 5C, the CFTM and the GPA according to the related art use the peak g3 of FIG. 4 having a lot of noise, so that a strain profile has a lot of noise, and thus an accurate strain cannot be illustrated. In contrast to this, the STC method according to the exemplary embodiment of the present invention uses the peaks g1 and g2 of FIG. 4 having a lot of noise, so that a strain profile has little noise, and thus it can be seen that a strain is clearly illustrated.

FIG. 5D is a diagram illustrating a result of an analysis of strain of a thin film by using the STC method according to the exemplary embodiment of the present invention.

FIG. 5E is a diagram illustrating a result of an analysis of strain of a thin film by using the CFTM method according to the related art.

FIG. 5F is a diagram illustrating a result of an analysis of strain of a thin film by using the GPA method according to the related art.

Referring to FIG. 5D, as the result of the analysis of strain of the thin film by using the STC method according to the exemplary embodiment of the present invention, an interface is locally sharp. In the result, according to the STC method according to the exemplary embodiment of the present invention, the two independent Bragg peaks g1 and g2 having high intensity are selected in the reciprocal lattice image of FIG. 4 and thus a ratio of noise to a signal is large, so that it can be seen that noise is little in the strain distribution analysis result.

In the meantime, referring to FIGS. 5E and 5F, as the result of the analysis of strain of the thin film by using the CFTM and the GPA method according to the related art, it can be seen that an interface is generally sharp due to low intensity of the Bragg peak g3 selected in the reciprocal lattice image of FIG. 4 and a strain distribution is not uniform. According to the CFTM and the GPA method according to the related art, it can be seen that a ratio of noise to a signal is low, so that a lot of noise is included in the strain distribution analysis result.

According to the method of analyzing strain of the thin film by using the STC method according to the present invention, it is possible to obtain a considerably accurate strain analysis result with minimal errors even in the case where strain of the thin film is complex.

According to the method of analyzing strain of the thin film by using the STC method according to the present invention, it is possible to measure shear strain, as well as axial strain, of a thin film.

As described above, the present invention has been described by the specific matters, such as a specific component, limited embodiments, and drawings, but these are provided only for helping general understanding of the present invention, and the present invention is not limited to the exemplary embodiments, and those skilled in the art will appreciate that various modifications, additions and substitutions are possible in the range without departing from the essential characteristic of the present invention. Accordingly, the spirit of the present invention is defined by the exemplary embodiment, and it should be construed that all technical spirits of the accompanying claims or equivalents or equivalent modifications thereof are included in the scope of the present invention.

What is claimed is:

1. A method of analyzing strain of a thin film by using a Strain Tensor Using Computational Fourier Transform Moiré (STC) method, the method comprising:
receiving two Bragg peaks selected from a reciprocal lattice image obtained by Fourier transforming a two-dimensional (2D) lattice image of a thin film;
shifting the two selected Bragg peaks to an origin point of the reciprocal lattice image;
calculating a moiré fringe pattern by Fourier-inverse-transforming the two Bragg peaks shifted to the origin point;
calculating a strain tensor by differentiating the calculated moiré fringe pattern; and
analyzing strain of the thin film by using the calculated strain tensor.

2. The method of claim 1, wherein the 2D lattice image of the thin film is a High-Resolution Transmission Electron Microscopy (HRTEM) image or a High-Angle Annular Dark-Field Scanning Transmission Electron Microscopy (HAADF-STEM) image.

3. The method of claim 1, wherein the two received Bragg peaks are non-colinear pole linear Bragg peaks.

4. The method of claim 1, wherein the two received Bragg peaks are the two Bragg peaks selected in order of largest intensity among the Bragg peaks except for the origin point in the reciprocal lattice image obtained by Fourier transforming the 2D lattice image of the thin film.

5. The method of claim 1, wherein for each of the two received Bragg peaks, Bragg peak information at a desired position in the reciprocal lattice image obtained by Fourier transforming the 2D lattice image of the thin film is selected by using a mask which makes an internal region of the mask maintain original information and an external region of the mask have 0.

6. The method of claim 1, wherein the strain tensor is a 2×2 strain tensor.
